(19) United States
(12) Patent Application Publication
(10) Pub. No.: US 2012/0192920 A1
(43) Pub. Date: Aug. 2, 2012

(54) Stacked Layer High Efficiency Solar Energy Collector

(75) Inventors: William Paul McCowan, Queenstown, MD (US); John Spence Hayes Chapman, JR., White Hall, MD (US); Michael Chase Chapman, White Hall, MD (US); Donald George Myers, Forest Hill, MD (US); Bruce Barton Vance, Arlington, VA (US)

(73) Assignee: Total Energy Renewable Power Systems, LLC, Kensington, MD (US)

(21) Appl. No.: 13/015,307

(22) Filed: Jan. 27, 2011

(51) Int. Cl. H01L 31/052; H01L 31/048; F24J 2/04

(52) U.S. Cl. 136/248; 126/634; 136/251

(57) ABSTRACT

An apparatus for improving the efficiency and usability of a solar energy collection panel is provided. In one embodiment, the collection panel comprises a plurality of layers. The first layer is a photovoltaic layer that converts the solar energy into electricity. That layer is coupled to a thermoelectric conversion layer that sinks heat from the photovoltaic layer and generates electricity based on the temperature difference between the top and bottom of the layer. A fluid heating layer is then coupled to and sinks heat from the thermoelectric layer to heat up a fluid, e.g. air or water. Each of these layers is stacked together and placed above an insulation layer that supports the layers and thermally isolates them from the surrounding environment. In another embodiment, a flexible coiled solar energy collection panel is provided. In still another embodiment, a modular rail system is provided for simple and customizable installation.

### BACKGROUND OF THE INVENTION

1. Field of the Invention

The field of the present invention relates to solar energy collection.

2. Background Art

Solar energy has long been useful to mankind, but it is only in the relatively recent past that mankind's technological advancements have allowed for more “modern” ways to capture, convert, and utilize, in the form of electricity and/or thermal energy, more of the solar energy that enters the earth's atmosphere.

One apparatus for converting this solar energy into electricity is a photovoltaic (PV) cell, or as it is more commonly known, a solar cell. Solar cells are semiconductors that are designed to produces electricity when exposed to light due to the photovoltaic effect. One of the major drawbacks of solar cells is their relatively poor energy conversion efficiency (e.g., 12-18%) although recent advancements are improving this conversion efficiency.

Another known apparatus for capturing solar energy is known as a thermal collector. A thermal collector, unlike a photovoltaic cell, does not convert the solar energy into electricity, but rather absorbs the thermal energy and couples that thermal energy to a fluid such as air or water. Thermal collectors are usually comprised of an absorption material that is heated by the solar energy. The absorber is coupled to some type of conduit, for example a tube or simply an enclosed hollow chamber. A fluid is then passed through this conduit and the heat collected by the absorber is then transferred to the fluid which then exits the system and can be utilized elsewhere.

Due to the relative inefficiency of PV cells, and because PV cells work better when they are not overheated, PV cells and thermal collectors are sometimes combined into a hybrid system to increase the overall conversion of solar energy. The thermal collector absorber collects the thermal energy captured by the PV cells and transfers that thermal energy to a fluid for use by other devices. This keeps the PV cells from overheating and allows them to operate in a more optimal range. Likewise, this hybrid system is more efficient overall, as some of the energy not captured by the PV cells is now captured by the thermal collector.

Both individual systems (i.e., PV or thermal collectors) and hybrid systems are usually designed at optimal output power breakpoints that are offer too little or too much output for the consumer. Likewise, even the hybrid systems still only capture a fraction of the solar energy that they intercept.

What is needed is a more efficient solar energy collector and one that offers the flexibility of designing the system to very specific output needs, lower initial cost, and provides easy future expansion. The invention set forth below provides these benefits and more.

### BRIEF SUMMARY OF THE INVENTION

In one embodiment, the present invention includes a system, comprising: a protective layer; a photovoltaic layer coupled to the protective layer; a thermoelectric conversion layer coupled to the photovoltaic layer; a fluid heating layer coupled to the thermoelectric conversion layer; and an insulation layer, wherein the protective layer and the insulation layer together sandwich the photovoltaic, thermoelectric conversion, and fluid heating layers.

In another embodiment, the present invention includes a stacked layer high efficient solar energy conversion module, comprising: a flexible photovoltaic layer; a flexible thermoelectric conversion layer coupled to the photovoltaic layer; a flexible fluid heating layer coupled to the thermoelectric conversion layer; and a flexible insulation layer, coupled to the flexible fluid heating layer, wherein the layers are sandwiched together and a finite length of the layer sandwich is rolled into a compact package.

In still another embodiment, the present invention includes a stacked layer high efficient solar energy conversion module, comprising: a flexible photovoltaic layer coupled to the protective layer; a flexible fluid heating layer coupled to the thermoelectric conversion layer; and a flexible insulation layer, coupled to the flexible fluid heating layer, wherein the layers are sandwiched together and a finite length of the layer sandwich is rolled into a compact package.

Another embodiment of the present invention relates to a modular solar power system, comprising a rail system and a stacked layer high efficient solar energy conversion module. The rail system further comprises: at least one pair of finite length lightweight material rails shaped into opposing channels; a first fluid conduit disposed within a channel of one of the at least one pair of rails; a second fluid conduit disposed within a channel of the opposing one of the at least one pair of rails; and a plurality of electrical conductors disposed within the channels of each of the at least one pair of rails. The stacked layer high efficient solar energy conversion module further comprises: a protective layer; a photovoltaic layer coupled to the protective layer with electrodes for communicating a generated voltage to a load; a thermoelectric conversion layer coupled to the photovoltaic layer electrodes for communicating a generated voltage to a load; a fluid heating layer coupled to the thermoelectric conversion layer with at least an inlet conduit and an outlet conduit; and a insulation layer, wherein the protective layer and the insulation layer together encompass the other layers, wherein the stacked layer high efficient solar energy conversion module is sized such that each module fits the rail system, and wherein, the first fluid conduit of the rail system is configured for connection to the inlet conduit of the fluid heating layer, the second fluid conduit of the rail system is configured for connection to the outlet conduit of the fluid heating system, and the electrodes from the photovoltaic and thermoelectric conversion layers are configured to connect to one or more of the plurality of electrical conductors of the rail system.

Further embodiments, features, and advantages of the present invention, as well as the structure and operation of the various embodiments of the present invention, are described in detail below with reference to the accompanying drawings.

It is to be understood that both the foregoing general description and the following detailed description are exemplary and explanatory only, and are not restrictive of the invention as claimed.

### BRIEF DESCRIPTION OF THE DRAWINGS/FIGURES

The accompanying figures, which are incorporated herein and form part of the specification, illustrate an improved solar energy collector, an alternative packaging design for a solar energy collector, and an improved modular installation platform for a solar energy collector. Together with the description, the figures further serve to explain the principles of an improved solar collection apparatus described herein and thereby enable a person skilled in the pertinent art to make and use the improved solar collection apparatus.

FIGS. 1A-1C are cross sectional views of an exemplary solar energy collection apparatus made according to an embodiment of the present invention. FIG. 1B shows an alternative configuration with an incorporated metal panel (e.g., tin roof). FIG. 1C shows an alternative configuration without any insulation support.

FIGS. 2A and 2B are illustrations of an alternative packaging design made according to an embodiment of the present invention.

FIG. 3 is a perspective view of an exemplary modular installation apparatus and method according to an embodiment of the present invention.

### DETAILED DESCRIPTION OF THE INVENTION

Reference will now be made in detail to embodiments of the present invention with reference to the accompanying figures, in which like reference numerals indicate like elements.

Embodiments of the present invention relate to methods and apparatus for capturing solar energy in relatively higher efficiency than known methods and providing a simpler packaging and installation design.

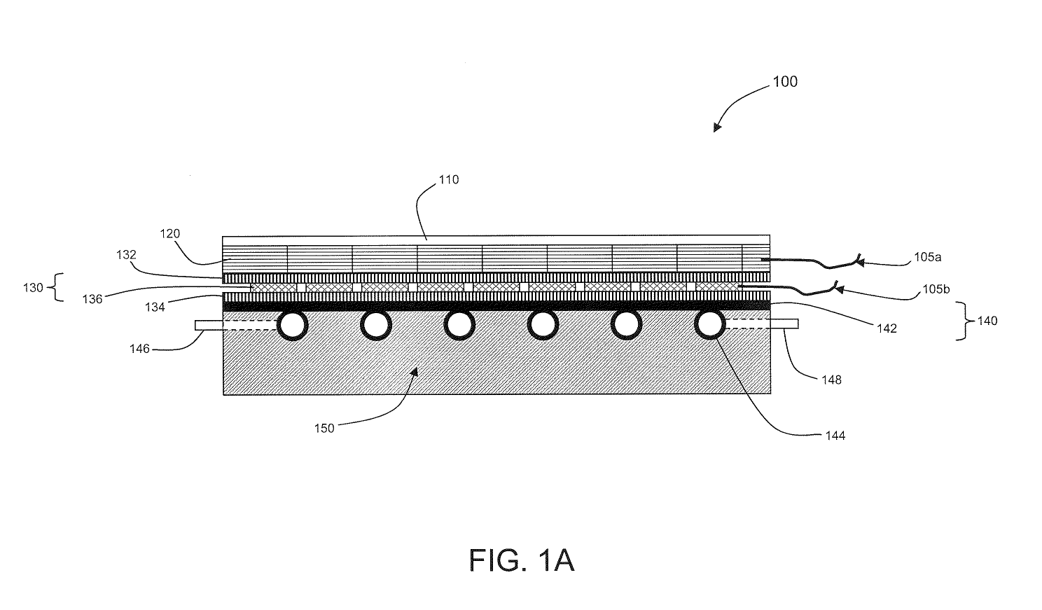

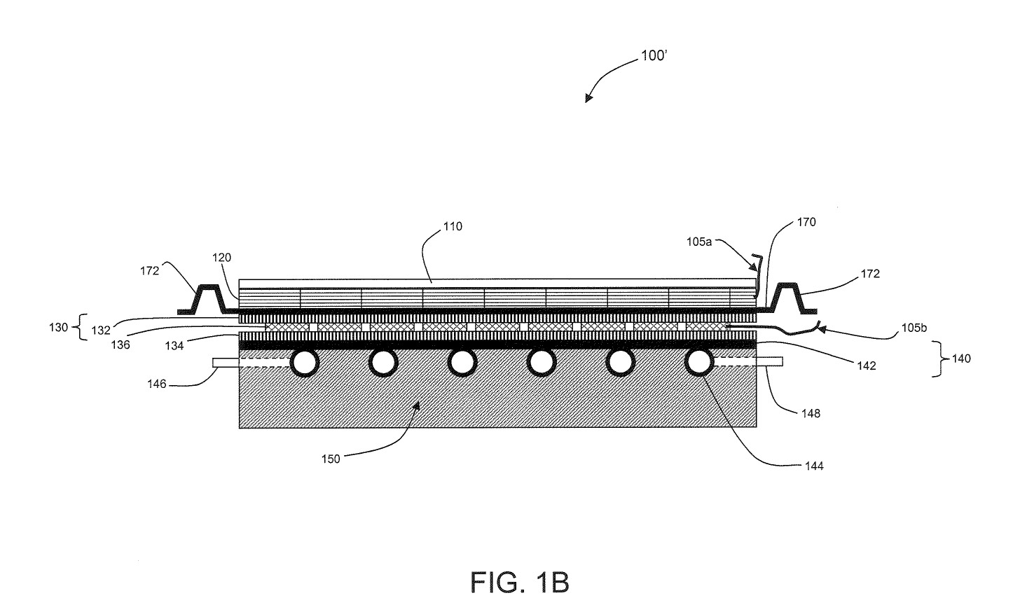

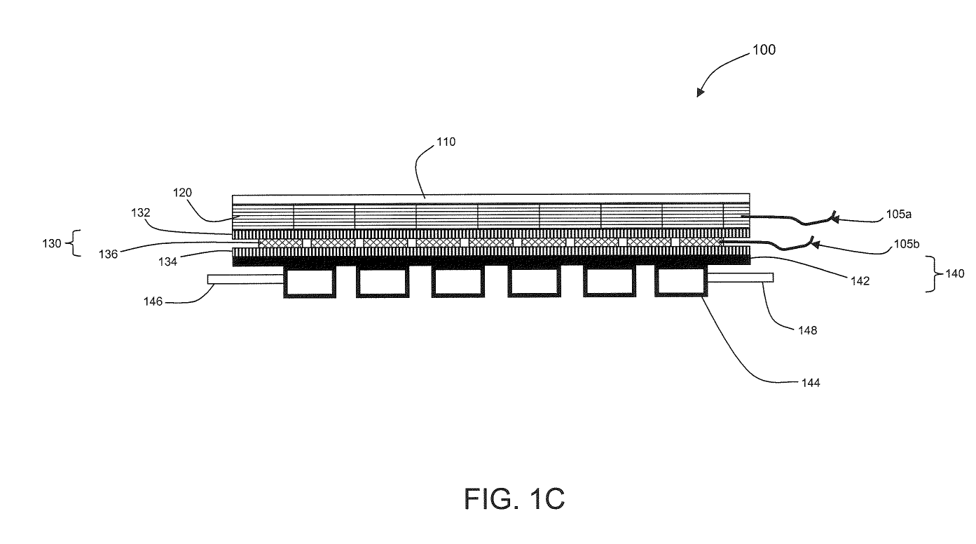

FIG. 1A is a diagram showing a cross-sectional view of an exemplary multi-stack solar energy collector panel 100. Multi-stack solar energy collector panel 100 can be part of an improved solar energy collection system (not shown) made according to an embodiment of the present invention. In one embodiment, multi-stack solar energy collector panel 100 can be used stand-alone to capture and process solar energy into electricity and a heated fluid, outputting a certain quantity of converted energy. In other embodiments, a plurality of exemplary multi-stack solar energy collector panels 100 can be incorporated into a multi-panel system. For example, a plurality of multi-stack solar energy collector panels 100 can be incorporated into a 2-panel system, a 4-panel system, a 6-panel system, an 8-panel system, or any other known multi-panel configuration of a solar energy collection system known to one of skill in the art.

Multi-stack solar energy collector panel 100 includes a protective layer 110, a photovoltaic (PV) layer 120, a thermo-electric layer 130, and a thermal collector layer 140. In one embodiment the multi-stack solar energy collector panel 100 also includes an insulation layer 150. In one embodiment, the protective layer 110 is a transparent glass or plastic protecting the more fragile PV layer. In another embodiment, the protective layer 110 is a flexible material that allows the solar energy to pass through it, but can be bent or rolled. In still another embodiment, the protective layer 110 is not needed.

PV layer 120 is comprised of a plurality of individual PV cells electrically coupled together. While the exact composition of the PV cells is not described and should not be limited by this disclosure, in at least one embodiment, the PV cells are designed in such a way that PV layer 120 is flexible or semi-flexible. In order to carry the electrical energy created by the photovoltaic effect in PV layer 120, this layer is provided with an output wire 105a, also known as an electrode.

Thermo-electric layer 130 which is coupled to PV layer 120 is comprised of a top 132 and a bottom 134 thermally conductive substrate that couples thermal energy (i.e., heat) from the adjoining layers. Top substrate 132 is coupled to PV layer 120 and sinks heat from this layer. Bottom substrate 134 is coupled to thermal collector layer 140 and sources heat to that layer. A thermal gradient is formed between top 132 and bottom 134 substrates. In at least one embodiment, top 132 and bottom 134 substrates are designed of a material or in such a way that they are effectively flexible or semi-flexible. Sandwiched between the two substrates 132/134 is a layer of semiconductor material 136 specifically designed and arranged to convert thermal energy into electricity when a temperature difference is present between the two substrates 132/134. While the exact composition and/or design of semiconductor material 136 is not described and should not be limited by this disclosure, in at least one embodiment, semiconductor material 136 is designed in such a way that thermoelectric layer 130 is flexible or semi-flexible. In order to carry the electrical energy created by the thermo-electric effect in thermo-electric layer 120, this layer is provided with an output wire 105b, also known as an electrode.

Thermal collector layer 140, also referred to herein as a fluid heating layer 140, is comprised of principally two parts, an absorber 142 and thermal conduits 144. Absorber 142 is coupled to bottom substrate 134 and sinks heat from bottom substrate 134. Thermal conduits 144 which are directly coupled to absorber 142 may be comprised of a channel or pipe, or simply be some type of enclosed passage-way capable of transporting in a sealed fashion a fluid therein. In at least one embodiment, thermal conduits 144 are laid out in an array of rows or in a meandering pattern in order to expose as much of conduits 144 to the heat from bottom substrate 134. The invention is not so limited as the thermal conduits 144 can be arranged in other patterns. The heat drawn from bottom substrate 134 is coupled to the fluid traveling through thermal conduits 144. In at least one embodiment, absorber 142 and thermal conduits 144 are designed of a material or in such a way that they are effectively flexible or semi-flexible. However, in at least one embodiment, absorber 142 is not required and thermal conduits 144 can simply be placed in close proximity to thermoelectric layer 120 and sink heat from bottom substrate 134. Thermal conduits 144 are supplied with an unheated fluid at an inlet port 146 and expel a heated fluid out of thermal conduits 144 at an outlet port 148. In one example, ports 146/148 can be coupled to a heating/cooling system of a building, such as a heat pump of an A/C system. In one embodiment the fluid is water. In another embodiment, the fluid is air. Antifreeze or other fluids can be used as desired depending upon particular operating conditions or applications. However, these exemplary embodiments should not limit the scope of the available fluids that could be used to couple the heat from thermal conduits 144. Each of these layers are coupled to each other and rest on an insulation layer 150. In at least one example, each of these layers are coupled to each other and rest directly on a mounting surface without an insulation layer 150.

Insulation layer 150, if used, is comprised of a non-thermal coupling material that does not sink the thermal energy from the other layers, and thus isolates the other layers 120/130/140 from the surrounding ambient environment. Insulation layer 150 may support the other layers 120/130/140 and may surround thermal conduits 144 (as shown in FIG. 1). In an embodiment, insulation layer 150 provides a mounting support for installing the layers into a energy collection system. In at least one embodiment, insulation layer 150 is designed of a material or in such a way that the layer 150 is effectively flexible or semi-flexible. In another embodiment, insulation layer 150 may also encompass, at the edges of a panel, the other layers 120/130/140 (not shown). In one embodiment, protective layer 110 and insulation layer 150 sandwich the other layers 120/130/140 creating a multi-stack solar energy collector panel 100. In another embodiment, there is no protective layer 110, but the remaining layers 120/130/140 along with the insulation layer 150 still create a multi-stack solar energy collector panel 100 without a protective top layer. In still another embodiment, there is no protective layer 110 or insulation layer 150, but the remaining layers 120/130/140 still create a multi-stack solar energy collector panel 100.

In one embodiment, a thermal adhesive (not shown) is placed (a) between top substrate 132 and PV layer 120, and (b) between bottom substrate 134 and fluid heating layer 140. In another embodiment, a thermal lubricant (also not shown) is placed (a) between top substrate 132 and PV layer 120, and (b) between bottom substrate 134 and fluid heating layer 140.

In another example, FIG. 1B features all the same elements as the multi-stack solar energy collector panel 100 of FIG. 1A and additionally incorporates a tin roof section 170 between PV layer 120 and thermo-electric layer 130. In this embodiment, thermo-electric layer 130 is not directly coupled to PV layer 120, instead the PV layer 120 is coupled to tin roof 170 (e.g., directly, or with thermal adhesive or lubricant). Tin roof 170 is then coupled to the top thermally conductive substrate 132 of thermoelectric layer 130 (e.g., directly, or with thermal adhesive or lubricant). In one example, multi-stack solar energy collector panel 100 is sized for convenient fit between risers 172 of the tin roof 170. Fluid and electrical connections to ports 146/148 and output wires 105a/105b can be simply and conveniently placed along the risers 172. The exposed tin roof 170 (i.e., not covered by a multi-stack solar energy collector panel 100) also functions as a thermal heat sink, absorbing solar thermal energy. Because of the tin roof 170 coupling to the top thermally conductive substrate 132 of thermo-electric layer 130, this absorbed thermal energy is coupled into thermo-electric layer 130 and converted to electricity further improving the efficiency of the system relative to the embodiment of FIG. 1A.

In another example, FIG. 1C features all the same elements as the multi-stack solar energy collector panel 100 of FIG. 1A except it does not have an insulation layer and the thermal conduits 144 are shown as rectangular channels. In this embodiment, the thermal conduits 144 serve as the support and mounting surface of the entire multi-stack solar energy collector panel 100.

When radiation (e.g., solar energy) illuminates the multi-stack solar energy collector panel 100, a plurality of conversions take place resulting in an increased amount of captured and converted energy thereby producing an increased efficiency system. Initially, the radiation is converted by PV layer 120 into electricity. However, PV layer 120 usually has a relatively low efficiency, although newer technological advances are improving the PV cells conversion capabilities. Because PV cells work most efficiently when they are not overheated and because radiation, particularly solar energy, can supply a significant amount of thermal energy, it is important to heat sink PV layer 120. Instead of installing a simple heat sink that draws heat away from PV layer 120 and uses fins or an absorber plate to dissipate the thermal energy to the surrounding air or a fluid, the present invention couples PV layer 120 to a thermo-electric conversion layer 130. In another embodiment, as shown in FIG. 1B, tin roof 170 serves as a heat absorber and coupling layer between layers 120 and 130. The thermal energy from PV layer 120 (and tin roof 170 if present) is effectively heat sunk by top thermally conductive substrate 132. Bottom thermally conductive substrate 134 is coupled to fluid heating layer 140, either by way of an absorber 142 or directly to thermal conduits 144, either of which draws heat away from bottom thermally conductive substrate 134. This creates a thermal gradient across thermoelectric semiconductor material 136 sandwiched between top 132 and bottom 134 thermally conductive substrates. This thermal difference is converted by thermoelectric semiconductor material 136 into electricity. The two sources of electricity from multi-stack solar energy collector panel 100, i.e., from PV layer 120 and thermo-electric conversion layer 130, may be combined or transmitted separately. A plurality of multi-stack solar energy collector panels 100 can be coupled electrically to produce a solar energy collection system with higher output capability than simply a single panel could provide. Each multi-stack solar energy collector panel 100 also includes a fluid heating layer 140, that as described earlier sinks heat from bottom thermally conductive substrate 134 by way of an absorber 142 or directly to the thermal conduits 144 and couples the remaining thermal energy to a fluid, typically water or air. Multi-stack solar energy collector panel 100 converts more of the radiation energy than the conventional PV, thermal collector, or hybrid PV/thermal collector systems. This increased efficiency produces a more useful product for the consumer, and depending on the purchase price may provide the consumer with a better output per cost ratio.

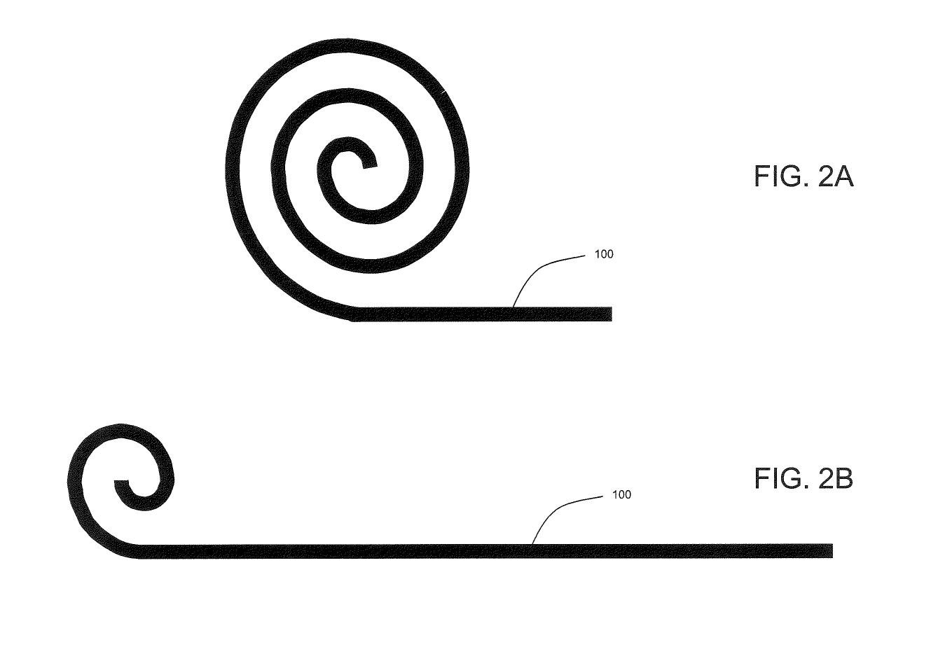

FIGS. 2A and 2B show an exemplary packaging and storage configuration of multi-stack solar energy collector panel 100. Multi-stack solar energy collector panel 100 is designed with the same specification as described in FIG. 1 above, but in the present embodiment each of the components are made in a flexible or semi-flexible form. This allows multi-stack solar energy collector panel 100 to be rolled into a compact package. FIG. 2A demonstrates rolled multi-stack solar energy collector panel 100 in an almost completely rolled condition. This configuration allows for simpler storage, transportation, and installation. FIG. 2B shows multi-stack solar energy collector panel 100 in an almost completely unrolled configuration. FIG. 2B would be more exemplary of multi-stack solar energy collector panel 100 at the time of installation. Installation would involve some type of fastener (not shown) to ensure that unrolled multi-stack solar energy collector panel 100 would remain lying flat.

The flexible rolled configuration shown in FIGS. 2A and 2B can also be utilized by a different stacked solar energy panel, one similar to the hybrid panels discussed above. That is, in one embodiment, FIGS. 2A and 2B contemplate a stacked solar energy panel that does not have thermoelectric conversion layer 130. However, as discussed with reference to FIG. 1, each of the layers would still need to be made of a flexible material so that the panel can be sufficiently bent in order to roll into a more compact package, as seen in FIG. 2A.

The rolled solar energy panel could be easily stored, transported, and installed without the inconveniences of the larger, rigid solar panels. Because the rolled footprint of the solar panel would be less than a flat solar panel of the same surface area, more could be stored and/or transported using known techniques. Each solar panel could be rated for a certain coverage area (based on some finite length and width of the panel) and power output. Then a consumer could purchase a plurality of rolls based on the available space for installation and the power output desired, assuming the capital is available to cover the cost of each additional roll.

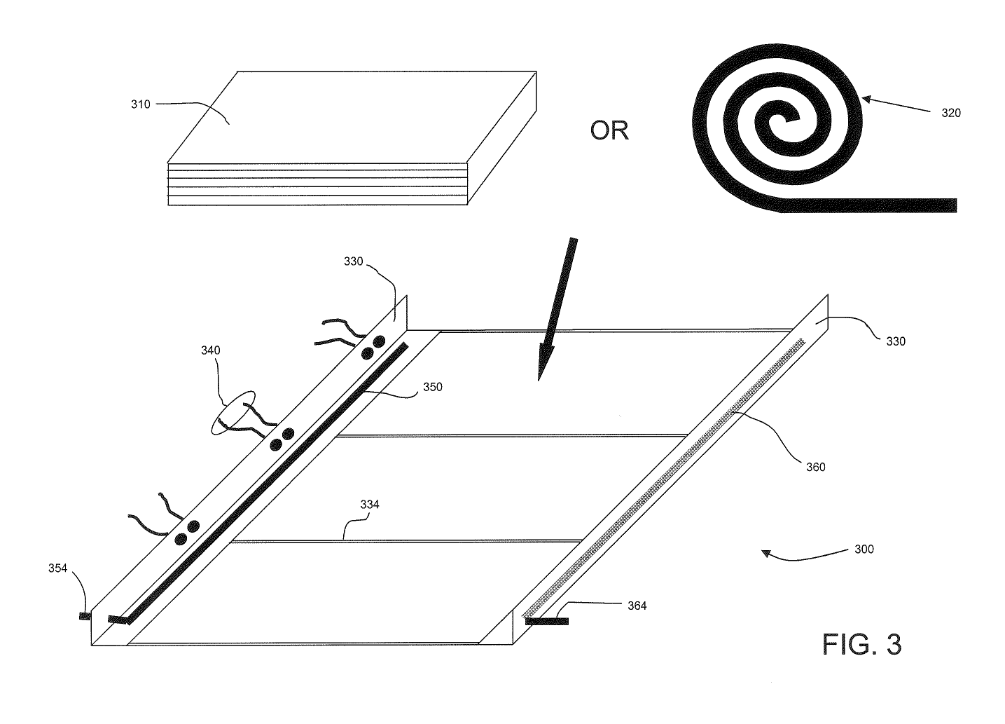

FIG. 3 is a prospective view of an exemplary modular rail system 300 for installation of a customizable solar energy collection system. In one embodiment, modular rail system 300 can be used stand-alone to provide electrical and fluid connection to a single solar panel or small quantity of solar panels. In other embodiments, a plurality of modular rail systems 300 can be incorporated into a multi-panel system. For example, a plurality of modular rail system 300 can be incorporated into a 2-panel system, a 4-panel system, a 6-panel system, an 8-panel system, or any other known multi-panel configuration of a solar energy collection system known to one of skill in the art.

Modular rail system 300 includes at least one pair of finite length rails 330, a plurality of alignment spacers 334, an inlet fluid manifold 350, an inlet fluid connection 354, an outlet fluid manifold 360 (hidden), an outlet fluid connection 364, and a plurality of electrical connections 340. Modular rail system 300 can accept either a conventional type stiff solar panel 310 or a flexible coiled solar panel 320 as described above. Rails 330 are made of a lightweight material such as aluminum. In one embodiment, rails 330 are L-shaped. In another embodiment, rails 330 are shaped into opposing channels. In other embodiments, rails 330 may have a square or rectangular cross-section. However, these exemplary embodiments should not limit the scope of the available shapes that rails 330 could take. Inlet fluid manifold 350 is disposed within the channel or interior of one of rails 330. Inlet fluid manifold 350 is coupled to inlet fluid connection 354 to supply a fluid to manifold 350. Inlet manifold 350 can then be connected to the inlet port of a thermal collector, for example, inlet port 146 in FIGS. 1A-1C. Outlet fluid manifold 360 is disposed within the channel or interior of the other one of rails 330. Outlet fluid manifold 360 is coupled to outlet fluid connection 364 to extract a fluid from manifold 360. Outlet manifold 360 can then be connected to the outlet port of a thermal collector, for example, outlet port 148 in FIGS. 1A-1C. There are a plurality of electrical connections 340 along the length of at least one of rails 330. Electrical connections 340 can be individually connected or combined together and connected to a load or additional electrical circuitry (not shown) in order to deliver power to a load. The electrical output from a PV panel and/or a thermo-electric circuit can be coupled to electrical connections 340, for example, output wires 105a/105b in FIGS. 1A-1C. In one embodiment, rails 330 are optionally spaced by a plurality of alignment spacers 334. In an embodiment, alignment spacers 334 not only locate rails 330 at an appropriate distance to receive at least one solar panel, they also support and guide the other two edges of the solar panel during installation and affixing to modular rail system 300. In at least one embodiment, the plurality of alignment spacers 334 are not needed.

Either a rigid solar panel 310 (as shown in FIG. 1) or a flexible rolled solar panel 320 (as shown in FIG. 2) is inserted between the two rails 330 and connected to inlet 350 and outlet 360 fluid manifolds and to electrical connections 340. Solar panel 310/320 is mounted to modular rail system 300 in individualized sections. System 300 can be designed and installed to accommodate as many panels as the mounting surface will allow. Exemplary modular rail system 300 shown in FIG. 3 can accommodate one to three of the solar panels 310/320. However, this disclosure does not limit the width and length of solar panels 310/320, nor the length of rails 330, therefore there is nothing herein limiting the number of solar panels 320/330 that can be installed per rail pair 330. In one embodiment, a plurality of rail pairs 330 are installed of the mounting surface providing additional solar energy conversion capacity. Electrical 340 and fluid 354/364 connections of the separate rail 330 pairs can remain separate or can be combined before being sent to the load or to additional electrical circuitry.

While various embodiments of the present invention have been described above, it should be understood that they have been presented by way of example only, and not limitation. It will be apparent to persons skilled in the relevant art that various changes in form and detail can be made therein without departing from the spirit and scope of the present invention. Thus, the breadth and scope of the present invention should not be limited by any of the above-described exemplary embodiments, but should be defined only in accordance with the following claims and their equivalents. All patents and publications discussed herein are incorporated in their entirety by reference thereto.

What is claimed is:

1. A system, comprising:
a photovoltaic layer;
a thermoelectric conversion layer configured to absorb thermal energy from the photovoltaic layer; and
a fluid heating layer coupled to the thermoelectric conversion layer.

2. The system of claim 1, further comprising:
a metallic panel located between the photovoltaic and thermoelectric conversion layers and configured to couple thermal energy from the photovoltaic layer and the exposed portions of the metallic panel to the thermoelectric conversion layer.

3. The system of claim 1, wherein each of the layers are flexible.

4. The system of claim 1, wherein the system is configured to be supported by and mounted on the fluid heating layer.

5. The system of claim 1, wherein the photovoltaic layer further comprises:
a plurality of photovoltaic cells electrically connected together; and
electrodes for communicating a generated voltage to a load.

6. The system of claim 1, wherein the thermoelectric conversion layer further comprises:
a pair of thermally conductive substrates;
a thermoelectric semiconductor material element sandwiched between the pair of thermally conductive substrates; and
electrodes for communicating a generated voltage to a load.

7. The system of claim 6, further comprising:
a thermal adhesive to bond one each of the pair of thermally conductive substrates of the thermoelectric conversion layer to the photovoltaic layer and fluid heating layer, respectively.

8. The system of claim 6, further comprising:
a thermal lubricant to thermally connect one each of the pair of thermally conductive substrates of the thermoelectric conversion layer to the photovoltaic layer and fluid heating layer, respectively.

9. The system of claim 1, wherein the fluid heating layer further comprises:
an inlet conduit configured to receive a fluid;
a transfer conduit coupled to the inlet conduit and configured to expose the fluid passing therein to remnant heat not converted to electricity by the photovoltaic layer or the thermoelectric conversion layer; and
an outlet conduit coupled to the transfer conduit and configured to receive the heated fluid from the transfer conduit at a elevated temperature above ambient.

10. The system of claim 9, wherein the fluid is water for use in a hot water system.

11. The system of claim 9, wherein the fluid is air for use in a forced air system.

12. The system of claim 1, further comprising:
a protective layer; and
an insulation layer, wherein the protective layer and the insulation layer together sandwich the photovoltaic, thermoelectric conversion, and fluid heating layers,
wherein the insulation layer is configured to isolate the photovoltaic, thermoelectric conversion, and fluid heating layers from the surrounding ambient environment.

13. The system of claim 12, wherein the insulation layer is configured to support the coupled photovoltaic, thermoelectric conversion, and fluid heating layers and to provide a mounting support for installing the system.

14. A stacked layer high efficient solar energy conversion module, comprising:
a flexible photovoltaic layer;
a flexible thermoelectric conversion layer coupled to the photovoltaic layer;
a flexible fluid heating layer coupled to the thermoelectric conversion layer; and
a flexible insulation layer, coupled to the flexible fluid heating layer,
wherein the layers are sandwiched together and a finite length of the layer sandwich is rolled into a compact package.

15. The module of claim 14, wherein the flexible photovoltaic layer further comprises:
a plurality of flexible photovoltaic cells electrically connected together; and
electrodes for communicating a generated voltage to a load.

16. The module of claim 14, wherein the flexible thermoelectric conversion layer further comprises:
a pair of thermally conductive flexible substrates;
a flexible thermoelectric semiconductor material element sandwiched between the pair of thermally conductive flexible substrates; and
electrodes for communicating a generated voltage to a load.

17. The module of claim 14, wherein the flexible fluid heating layer further comprises:
a flexible inlet conduit configured to receive a fluid at ambient or cooler temperature;
a flexible transfer conduit coupled to the flexible inlet conduit and configured to expose the fluid passing therein to remnant heat not converted to electricity by the flexible photovoltaic layer or the flexible thermoelectric conversion layer; and
a flexible outlet conduit coupled to the flexible transfer conduit and configured to receive the heated fluid from the flexible transfer conduit at a elevated temperature above ambient.

18. A stacked layer high efficient solar energy conversion module, comprising:
a flexible photovoltaic layer;
a flexible fluid heating layer coupled to the flexible photovoltaic layer; and
a flexible insulation layer, coupled to the flexible fluid heating layer,
wherein the layers are sandwiched together and a finite length of the layer sandwich is rolled into a compact package.

19. The module of claim 18, wherein the flexible photovoltaic layer further comprises:
a plurality of flexible photovoltaic cells electrically connected together; and
electrodes for communicating a generated voltage to a load.

20. The module of claim 18, wherein the fluid heating layer further comprises:
a flexible inlet conduit configured to receive a fluid at ambient or cooler temperature;
a flexible transfer conduit coupled to the flexible inlet conduit and configured to expose the fluid passing therein to remnant heat not converted to electricity by the flexible photovoltaic layer or the flexible thermoelectric conversion layer; and
a flexible outlet conduit coupled to the flexible transfer conduit and configured to receive the heated fluid from the flexible transfer conduit at a elevated temperature above ambient.

21. A modular solar power system, comprising:
a rail system, comprising:
at least one pair of finite length lightweight material rails shaped into opposing channels;
a first fluid conduit disposed within a channel of one of the at least one pair of rails;
a second fluid conduit disposed within a channel of the opposing one of the at least one pair of rails; and
a plurality of electrical conductors disposed within the channels of each of the at least one pair of rails; and
a stacked layer high efficient solar energy conversion module, comprising:
a photovoltaic layer coupled to the protective layer with electrodes for communicating a generated voltage to a load;
a thermoelectric conversion layer coupled to the photovoltaic layer electrodes for communicating a generated voltage to a load;
a fluid heating layer coupled to the thermoelectric conversion layer with at least an inlet conduit and an outlet conduit; and
a insulation layer, wherein the protective layer and the insulation layer together encompass the other layers,
wherein the stacked layer high efficient solar energy conversion module is sized such that each module fits the rail system, and
wherein, the first fluid conduit of the rail system is configured for connection to the inlet conduit of the fluid heating layer, the second fluid conduit of the rail system is configured for connection to the outlet conduit of the fluid heating system, and the electrodes from the photovoltaic and thermoelectric conversion layers are configured to connect to one or more of the plurality of electrical conductors of the rail system.

22. The system of claim 21, wherein the photovoltaic layer further comprises:
a plurality of photovoltaic cells electrically connected together.

23. The system of claim 21, wherein the thermoelectric conversion layer further comprises:
a pair of thermally conductive substrates; and
a thermoelectric semiconductor material element sandwiched between the pair of thermally conductive substrates.

24. The system of claim 21, wherein the fluid heating layer further comprises:
a transfer conduit coupled to the inlet conduit and configured to expose the fluid passing therein to remnant heat not converted to electricity by the photovoltaic layer or the thermoelectric conversion layer.

25. The system of claim 21, wherein each of the layers are flexible.

26. The system of claim 25, wherein the layers are sandwiched together and a finite length of the layer sandwich is rolled into a compact package.

27. The system of claim 26, wherein the finite length of the layer sandwich rolled into the compact package is sized such that each package fits the rail system.
